(19) United States
(12) Patent Application Publication
(10) Pub. No.: US 2025/0164551 A1
(43) Pub. Date: May 22, 2025

(54) Electronic Component and Method of Operating Such a Component

(71) Applicant: TDK-Micronas GmbH, Freiburg im Breisgau (DE)

(72) Inventors: Thilo Rubehn, Gundelfingen (DE); David Muthers, Denzlingen (DE); Timo Kaufmann, Emmendingen (DE)

(21) Appl. No.: 18/955,427

(22) Filed: Nov. 21, 2024

(30) Foreign Application Priority Data
Nov. 22, 2023 (DE) 10 2023 132 611.2

(51) Int. Cl. G01R 31/28; H01L 25/18; H10D 1/68

(52) U.S. Cl. CPC G01R 31/2884; G01R 31/2853; H01L 25/18; H10D 1/68

(57) ABSTRACT

An electronic component has an integrated circuit, a capacitor, and several conductors that are connected by way of bonding wires with contact elements of the integrated circuit. Two conductors are connected to one another by way of a current path, in which the capacitor, a first electrically conductive layer connecting a first connector of the capacitor to the first conductor, and a second electrically conductive layer connecting a second connector of the capacitor to the second conductor are arranged. The integrated circuit has an impedance measuring device to measure the impedance between the conductors that are connected to one another by way of the current path, which device can be connected to the first conductor by means of a switch. The impedance measuring device is configured to determine the equivalent ohmic series resistance between the conductors. This enables the contact quality of the layers to be tested.

### CROSS-REFERENCE TO RELATED APPLICATION

This application claims priority to German Patent Application No. 10 2023 132 611.2 filed Nov. 22, 2023, the disclosure of which is hereby incorporated by reference in its entirety.

### BACKGROUND OF THE INVENTION

### Field of the Invention

The invention relates to an electronic component that has at least one integrated circuit (IC), at least one capacitor, and several electric conductors, each having at least one first contact point that is connected by means of a bonding wire or similar connecting element to a contact element of the integrated circuit assigned to the respective conductor, whereby at least two conductors, in addition to the first contact point, each have at least a second contact point, and whereby the second contact points of this conductor are connected to one another by means of at least one current path, in which the capacitor, a first electrically conductive layer connecting a first terminal of the capacitor to the second contact point of a first conductor, and a second electrically conductive layer connecting a second terminal of the capacitor to the second contact point of a second conductor are arranged. In addition, the invention relates to a method for operating this type of component.

### Description of Related Art

An electronic component of the type mentioned initially is known from US 2018/0061784 A1, having multiple integrated circuits in an IC housing arranged on a lead frame. The lead frame has several electric conductors designed as lead frame contacts separate from one another, each have a first contact point that is connected, by means of a bonding wire, to a contact element of an integrated circuit allocated to the applicable conductor. Three conductors each have a minimum of a second contact point in addition to the first contact point. A second contact point of a first conductor is connected to a second contact point of a second conductor by means of a first capacitor arranged in the IC housing. In a corresponding manner, a second contact point of a second conductor is connected to a second contact point of a third conductor by means of a second capacitor also arranged in the IC housing.

The capacitors are intended as stabilization filters in this configuration and therefore do not participate in the actual function of the electric component. In an absolutely interference-free environment with an ideal power supply, these would not be required at all for correct operation of the component. In practical application however, the environment, in particular for automobile electronics, is subject to high levels of interference, which cause undesired voltage fluctuations both through severe load changes and radiated coupling in cable harnesses. These effects and phenomena are generalized under the term electromagnetic compatibility (EMC). The area is expanded by occurrences of electrostatic discharges (ESD), which are particularly relevant during installation and maintenance activities. For the reliable filter function of the capacitors, the quality of the electrical connections is of particular importance. On the other hand, electrical connections of insufficient quality lower the required robustness of the component EMC and ESD.

Many manufacturers of integrated circuits already offer components with integrated capacitors. For example, the integrated Hall sensors of type HAC830 from the portfolio of the applicant (TDK-Micronas GmbH) have two hybrid capacitors integrated in a housing together with a sensor IC. The necessity to provide capacitors at the system level therefore is eliminated. This increase in the degree of integration generally supports thereby the reduction of effort and costs in the further processing and in the use of the electronic component.

So, for example, WO 2007/067422 A1 reveals a sensor housing in which an external ceramic or PCB (printed circuit board) carrier can be fully eliminated. For this purpose, a sensor is electrically and mechanically connected to an ASIC and several capacitors and additional components on a “lead frame” substrate. A lead frame comprises several individual metal tracks that run from inside the encapsulated component to the outside and serve there as a connecting contact. In addition, the metal tracks of conductors of the lead frame serve within the housing as a mechanical carrier and/or electrical connector for the various integrated assemblies and can also be arranged as their housing-internal wiring. Conductive and non-conductive adhesives are used for the mechanical and/or electrical connection. Alternatively, soldering technologies are used to establish the connections. The electrical connection of the integrated circuits or sensor chip takes place by means of bonding wires, which are arranged between the bonding pads on the integrated circuits and contact points on the metal tracks or conductors, or respectively, the connection contacts of the lead frame.

In a harsh environment such as automobile electronics, the electrical connections are subject to particularly high physical stresses, such as increased absolute temperatures and rapid changes in temperature. It is known that this type of stress profile accelerates the aging process in electrically conductive adhesives, which leads finally to degradation in contact quality.

### SUMMARY OF THE INVENTION

The task of the invention therefore is to create an electronic component of the type mentioned initially and a method to operate such a component that enables determining in a simple manner a degradation of the electrically conductive layers intended for the connection of at least one capacitor. In safety applications this task is a requirement.

With regard to the component, this task is accomplished as described herein. These stipulate that the integrated circuit has an impedance measuring device to measure the impedance between the first contact points of the conductors connected to one another by means of the at least one current path, that at least one measurement signal connection of the impedance measuring device can be connected by means of at least one switch on at least one of these first contact points, and that the impedance measuring device is configured for determining the equivalent ohmic series resistance between the first contact points connected to one another by the at least one current path.

With regard to the method, the task noted above is accomplished as described herein. These stipulate that the integrated circuit be placed in a test mode, in which an impedance device, present on the integrated circuit, for acquiring an impedance measurement signal at the conductors connected to one another by means of the current path is connected between them, and that the equivalent ohmic series resistance of the conductors connected to one another by means of the current path be determined using the impedance measurement signal.

The impedance between the conductors connected to one another by means of the current path can be represented with the help of an electric series equivalent circuit diagram, which has an ohmic series resistance and therefore a reactance connected in series that has at least one capacitance or a capacitive component. The invention is based on the knowledge that the ohmic series resistance corresponding to the degradation of the electrically conductive layers arranged between the connectors of the capacitor and the second contact points of the conductor assigned to these increases (degradation) with increasing age and/or increasing service life, while the capacitance of the capacitor mostly remains constant.

Due to the shift, which accompanies the degradation, of the effective threshold frequency of a filter that has the capacitance and the ohmic series resistance interference that occurs is no longer suppressed in the manner required. As a result, the function of the integrated circuit can be negatively impacted when exposed to sufficiently high interference. Since the degradation of the electrically conductive layers represents a characteristic inherent in the system and that in addition depends on the budget of physical stresses, it is all but unavoidable.

The contact quality of the electrical connection between the capacitor connectors and the conductors assigned to them can also be impacted by fluctuations caused by the production process. This results in different values for the equivalent ohmic series resistance. Higher ohm electrical connections as a consequence achieve a critical point of degradation earlier than a priori comparable low ohm electrical connections. The expected lifespan of the integrated circuit for safe operation therefore fluctuates proportional to the initial quality of the electrical connection at the end of production. In other words, an initially increased ohmic series resistance more quickly approaches a threshold value that is critical in use.

Through the complete integration of the impedance measuring device as a part in the IC, the measurement of equivalent ohmic series resistance can take place even after the commissioning of the component, practically during the entire lifespan of the integrated circuit. At the same time, if needed the measurement can be repeated at predetermined time intervals and/or after switching on the component, before the component begins its normal operation.

The impedance measuring device according to the invention has at least one switch with which the current path to be tested is connected to the impedance measuring device. It should be noted that this switch can also be structured in electronic form, fully IC integrated. In the same manner, several of these switches can also be provided in order to connect additional hybrid integrated capacitors to the impedance measuring device.

The at least one capacitor can also be used as a support or decoupling capacitor, depending on the application. If generating direct current voltage for the power supply, one speaks of a smoothing or filter capacitor.

The capacitors suppress voltage fluctuations on the conductors. Both overvoltage peaks and undervoltage peaks are suppressed. The voltage stabilization is not limited to supply voltages, but is also targeted at the signal level of digital inputs and outputs and also at analog outputs, with a bandwidth limiting effect. As a result, the filter effect suppresses both conducted interference and coupled interference. Generally speaking, capacitors thereby increase the robustness of the electronic components in the area of electromagnetic compatibility (EMC) and electrostatic discharge (ESD). The latter are not only limited to interference in operation, they can also damage the electronic component. For this reason, corresponding configurations for external connection of an integrated circuit are typically stipulated in the manufacturer's data sheets or recommended in a specific manner.

In a preferred embodiment of the invention, the impedance measuring device has a test signal generator to supply the at least one capacitor with a test signal. The test signal can be designed in particular as a sine wave, as a step function, or as a square wave. If the test signal is designed as a step function, the equivalent ohmic series resistance can take place through evaluation of the charging curve of the transient charging current of the capacitor.

It is advantageous when the impedance measuring device
has a current measuring device to record a current flowing between the test signal generator and the conductor supplied with the test signal
has a voltage measuring device to record the voltage on the conductor supplied with the test signal
has a phase differential measuring device to measure the phase difference between this current and this voltage

The series resistance hereby can be determined as a real part of the impedance from the phase shift and if necessary, the measured impedance.

In a practical embodiment of the invention, the integrated circuit has a signal processing device that is connected to the current measuring device, the voltage measuring device, and the phase differential measuring device, and is designed to determine the equivalent ohmic series resistance of the electric connection between the second contact points of the conductors connected to one another through the at least one capacitor from the recorded phase difference, the measured current, and the measured voltage. The signal processing device, for example, can include a scanning device, an analog/digital converter, a data memory, and/or a microprocessor with a program memory. When determining the equivalent ohmic series resistance, the capacitance of the capacitor in the current path and/or the value of an impedance connected parallel to the current path (e.g., internal resistance of a supply voltage source connected to the conductors) can be taken into account. The corresponding values can be stored in the data memory, for example. Alternatively, impedances connected in parallel can be separated by additional switches to be provided during the period of the current path measurement. This applies in particular for the internal resistance of a connected supply voltage source. The supply of the IC would then be interrupted on the system side for the time period of the measurement. The determination in this case would run with the residual energy stored in the IC, and the result would be stored. When subsequently switched on again, according to the invention, the measurement result would be available for comparison of a function test. This type of process, for example, is practical for each shutdown and renewed startup of the system.

By providing at least one additional switch, both inputs of the impedance measuring device can be separated. As such, the current path of the impedance measuring device is fully isolated. This is required, for example, when checking a differential signal output. In the case of single-ended capacitors, the measurement is not grounded, with simultaneous isolation of the ground on the supply side.

In a further development of the invention, the impedance measuring device has an output to output a measurement signal for the equivalent ohmic series resistance, whereby the integrated circuit has a comparator that, to compare the equivalent ohmic series resistance with at least one predefined threshold value, has a first comparison signal input connected to the output to output the measurement signal for the equivalent ohmic series resistance, and a second comparison signal input connected to a reference encoder. At the same time, if a threshold value is exceeded an error condition is displayed and, in particular, a warning or alarm signal is output from the electronic component. If necessary, the warning or alarm signal can be reset after falling below the threshold value.

The integrated circuit preferably has a data memory in which the determined equivalent ohmic series resistance and/or result of the comparison performed with the comparator can be stored. It is even possible, at different points in time, to store equivalent ohmic series resistances (R₃, R₆) in the data memory, to read out these ohmic series resistances (R₃, R₆) from the data memory, and to subject them to trend recognition in order, if necessary, to advise that exceeding the threshold value is impending.

In an advantageous embodiment of the invention, the integrated circuit has at least one magnetic field sensor. The magnetic field sensor can be designed as a Hall sensor or magnetoresistive sensor. This type of magnetic field sensor can be used in particular in various forms in motor vehicles, for example, as position sensors to record an angle of rotation or a linear movement, or as a position encoder.

In a preferred embodiment of the invention, the component has a closed plastic housing that encloses the integrated circuit and the at least one capacitor. The plastic housing protects the integrated circuit and the at least one capacitor from environmental influences.

It is advantageous when the conductors are designed as lead frame contacts. This saves an additional printed circuit board on and/or in which the conductors are arranged.

In another practical embodiment of the invention, the conductors are designed as conductor paths arranged on and/or in a printed circuit board, or have such conductor paths whereby the conductor paths are arranged on a printed circuit board enclosed in a plastic housing. At the same time at least one of the conductors can comprise at least two conductor paths that are connected to one another by at least one bonding wire arranged in the housing. Furthermore, it is advantageous when at least two conductor paths are connected to lead frame contacts using bonding wires arranged in the plastic housing, and when these lead frame contacts preferably each have at least one exposed contact surface on the outside of the housing.

Additional advantageous embodiments of the invention are the subject of dependent claims.

### BRIEF DESCRIPTION OF THE DRAWINGS

In the following, an exemplary embodiment of the invention will be explained in greater detail, using the drawing. It shows:

FIG. 1 a top view of a first exemplary embodiment of an electronic component, whereby the housing of the component is only represented as a dashed line along its outer contour,

FIG. 2 a side view of the electronic component from FIG. 1 from the direction identified with II,

FIG. 3 a side view of the electronic component from FIG. 1 from the direction identified with III,

FIG. 4 a circuit diagram of an impedance measuring device for determining the equivalent ohmic series resistance of current paths contained in the electronic component, in which capacitors are arranged, and

FIG. 5 a top view of a second exemplary embodiment of an electronic component, whereby the housing of the component is represented as transparent.

### DESCRIPTION OF THE INVENTION

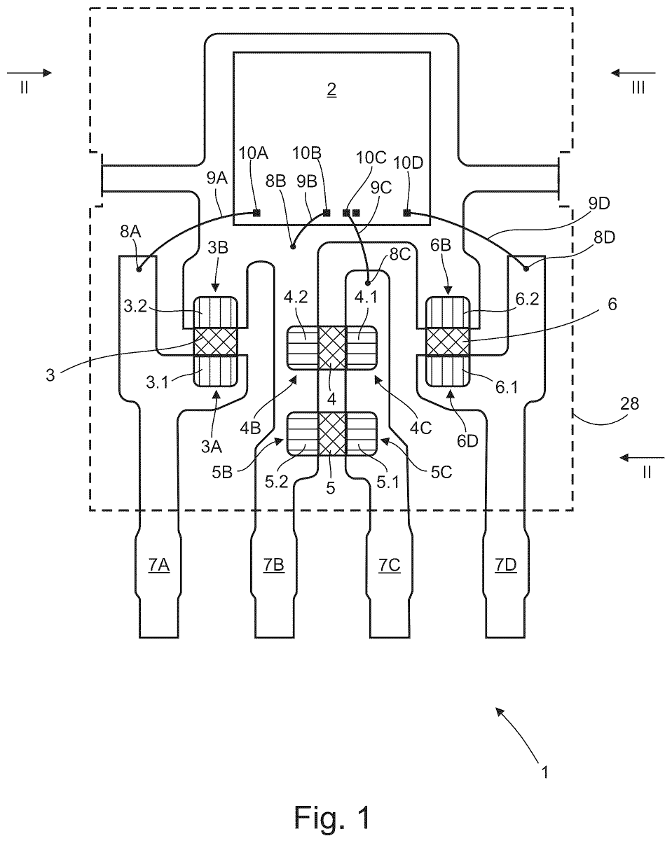

An electronic component labeled as a whole as 1 in FIG. 1 has a semiconductor chip with an integrated circuit 2, several hybrid capacitors 3, 4, 5, 6 integrated in the component 1, and several electric conductors 7A, 7B, 7C, 7D designed as lead frame contacts. Every conductor 7A, 7B, 7C, 7D each has a first contact point 8A, 8B, 8C, 8D, which is connected, by way of at least one bonding wire 9A, 9B, 9C, 9D, to a contact element 10A, 10B, 10C, 10D of the integrated circuit 2, structured as a bond pad, that is assigned to the applicable conductor 7A, 7B, 7C, 7D.

In addition, every conductor 7A, 7B, 7C, 7D each has at least one second contact point 3A, 3B, 4B, 4C, 5B, 5C, 6B, 6D that is connected by means of a current path, in each instance, to a second contact point 6D, 6B, 5C, 5B, 4C, 4B, 3B, 3A of a further conductor 7D, 7C, 7B, 7A. A capacitor 3, 4, 5, 6 and two electrically conductive layers 11A, 11B, 12A, 12C, 13D, 13B each are arranged in every current path, by way of which the connectors 3.1, 3.2, 4.1, 4.2, 5.1, 5.2, 6.1, 6.2 of the applicable capacitors 3, 4, 5, 6 are connected to the second contact point 3A, 3B, 4B, 4C, 5B, 5C, 6B, 6D assigned to them. The capacitors 3, 4, 5, 6 serve to suppress EMC interference and electrostatic discharge voltages in the conductors 7A, 7B, 7C, 7D.

The integrated circuit 2 is designed as a magnetic field sensor that has a first differential output connected to a first conductor 7A by means of a first bonding wire 9A, a voltage supply connector for a first voltage supply potential connected to a second conductor 7B by means of a second bonding wire 9B, a voltage supply connector for a second voltage supply potential connected to a third conductor 7C by means of a third bonding wire 9C, and a second differential output connected to a fourth conductor 7D by means of a fourth bonding wire 9D. By means of the differential outputs, magnetic field measurement values from the integrated circuit 2 can be transmitted to an external control device connected to the conductors 7A, 7D.

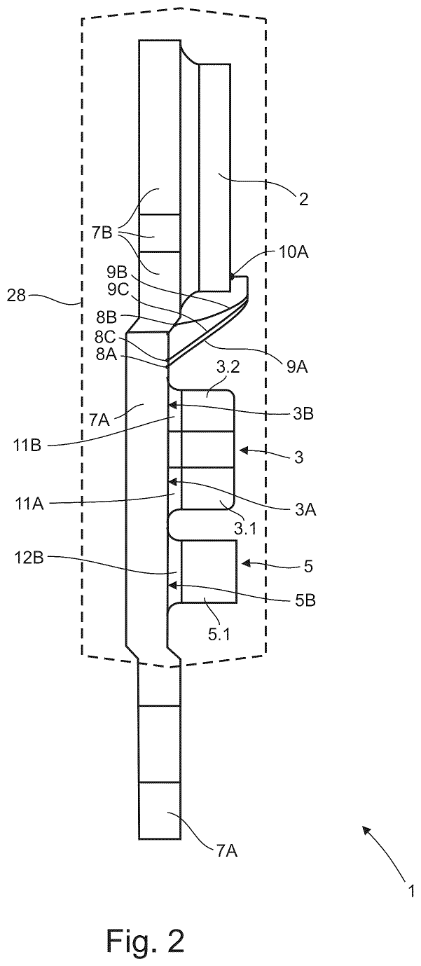

As can be seen in FIG. 2, a first connector 3.1 of a first capacitor 3 is connected to a second contact point 3A of the first conductor 7A by way of a first electrically conductive layer 11A. A second connector 3.2 of the first capacitor 3 is connected to a second contact point 3B of the second conductor 7B by way of a second electrically conductive layer 11B.

A first connector 4.1 of a second capacitor 4 is connected to a second contact point 4C of the third conductor 7C by way of an additional first electrically conductive layer. A second connector 4.2 of the second capacitor 4 is connected to an additional second contact point 4B of the second conductor 7B by way of an additional second electrically conductive layer.

A first connector 5.1 of the third capacitor 5 is connected to a second contact point 5C of the third conductor 7C by way of an additional first electrically conductive layer 12C. In FIGS. 1 and 2 it can be seen that a second connector 5.2 of the third capacitor 5 is connected to an additional second contact point 5B of the second conductor 7B by way of an additional second electrically conductive layer 12B.

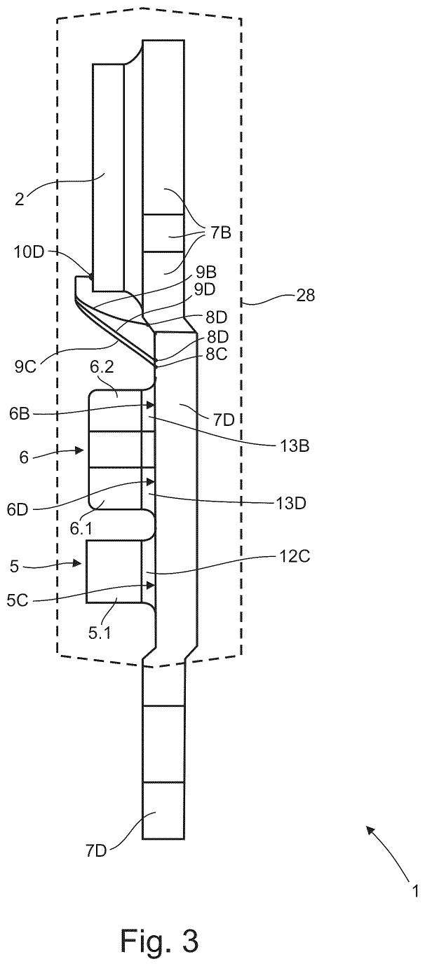

As can additionally be seen in FIG. 3, a first connector 6.1 of a fourth capacitor 5 is connected to a second contact point 6D of the fourth conductor 7D by way of an additional first electrically conductive layer 13D. A second connector 6.2 of the fourth capacitor 6 is connected to an additional second contact point 6B of the second conductor 7B by way of an additional second electrically conductive layer 13B.

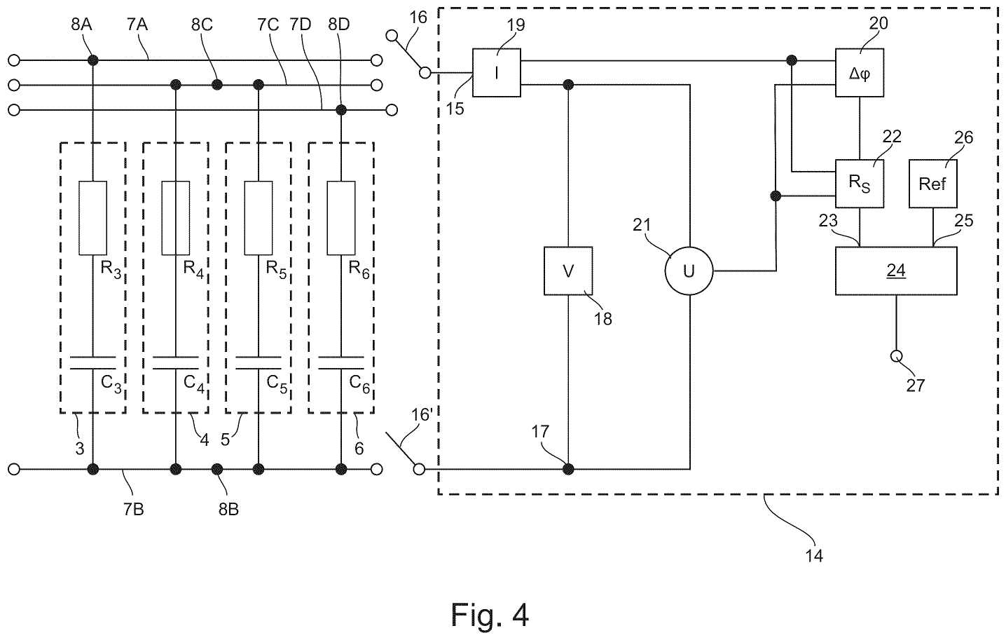

To measure the impedance between each of the conductors 7A, 7B, 7C, 7D connected to one another by means of the current path, in each instance, the integrated circuit 2 has an impedance measuring device 14. As can be seen in FIG. 4, the impedance measuring device 14 has a first measuring connector 15 that can be connected optionally or alternately by means of a first switch 16 designed as a multiplexer, to the first contact point 8A of the first conductor 7A, the first contact point 8C of the third conductor 7C or the first contact point 8D of the fourth conductor 7D. The first contact point 8B of the second conductor 7B can be connected to a second measuring connector 17 of the impedance measuring device 14 by way of a second switch 16′. The second switch 16′ is closed when the first measuring connector 15 is connected to a first contact point 8A, 8C, 8D by way of the first switch 16. Otherwise, the second switch 16′ is open.

To apply a test signal containing an AC voltage component to the measuring connectors 15, 17, the impedance measuring device 14 has a test signal generator 18 that has a first and a second test signal generator connector, at which a sine-wave shaped test voltage can be output.

The first test signal generator connector is connected to the first measuring connector 15 by way of a current measuring device 19, and the second test signal generator connector is connected to the second measuring connector 17. An output of the current measuring device 19 is connected to a first input of a phase differential measuring device 20 to output a current measurement signal.

To measure the electrical voltage between the measuring connectors 15 and 17, the impedance measuring device 14 has a voltage measuring device 21 that is connected to a first measuring connector with the first test signal generator connector, and to a second measuring connector with the second test signal generator connector. An output of the voltage measuring device 21 is connected to a second input of the phase differential measuring device 20 to output a voltage measurement signal.

An output of the phase differential measuring device 20 is connected to a first input of a signal processing device 22 to output a phase differential measurement signal corresponding to the phase difference between the current measurement signal and the voltage measurement signal. A second input of the signal processing device 22 is connected to the current measurement signal output of the current measuring device 19, and a third input of the signal processing device 22 is connected to the voltage measurement signal output of the voltage measuring device 21.

The impedance that depends on the frequency of the test voltage can be expressed either as the amount of impedance and phase or in the form of a common equivalent circuit diagram consisting of Resistance R, Capacitance C and Inductance L in a series circuit. The RLC equivalent circuit diagram intrinsically contains the frequency dependency or frequency response, respectively.

In the present invention, based on the known structure, the series circuit of an ohmic resistance and a capacitance is used as an equivalent circuit diagram for the at least one current path to be tested that is connected to measuring connectors 15, 17, in which the capacitors 3, 4, 5, 6 as well as the first and second electrically conductive layer 11A, 11B, 12B, 12C, 13B, 13D are arranged.

As a further simplification, a known value for the amount of capacitance, for example the nominal value of the capacitors 3, 4, 5, 6 arranged in the at least one current path, can be assumed. Using this assumption, it is possible to perform the measurement with only one frequency in the case of harmonic excitation by the test signal.

The signal processing device 22 is therefore designed to determine the equivalent ohmic series resistance of at least one equivalent circuit connected between the measuring connectors 15, 17 and equivalent to the at least one current path connected to the measuring connectors 15, 17, which has the series resistance and a capacitance connected with it in series.

An output of the signal processing device 22 is connected to a first comparison signal input 23 of a comparator 24. A second comparison signal input 25 is connected to a reference encoder 26. An output of the comparator 24 is used to output a result signal that depends on the result of the comparison. This indicates a fault if the determined equivalent ohmic series resistance is greater than a threshold value specified and predetermined by the reference encoder 26. If a threshold value is exceeded, the component 1 can trigger a warning or alarm signal. In this regard it is conceivable that multiple threshold values can be set. Accordingly, the corresponding warning or alarm signals can be assigned to different hierarchies or priorities.

Using the switch 16, the first measuring connector 15 is connected sequentially with each one of the conductors 7A, 7C, 7D. When the first measuring connector 15 is connected to the first conductor 7A, the impedance measuring device 17 determines the equivalent ohmic series resistance R₃ of a first current path containing the first capacitor 3.

When the first measuring connector 15 is connected to the third conductor 7C, the impedance measuring device 17 determines the equivalent ohmic series resistance R₄·R₅/(R₄+R₅) of the parallel circuit from a second current path having the second capacitor 4 and a third current path having the third capacitor 5.

When the first measuring connector 15 is connected to the fourth conductor 7D, the impedance measuring device 17 determines the equivalent ohmic series resistance R₆ of a current path containing the fourth capacitor 6.

Alternatively, as part of the simplifying assumptions, it is also possible to apply a step function test signal to at least one of the current paths and to determine the equivalent ohmic series resistance for the at least one current path using transient assessment of the current flow. The transient current flow in this configuration can also be called charging curve.

The determination of the equivalent ohmic series resistance in the operation of the electronic component 1 can be invoked externally by a controller, or be a part of each function executed, such as, for example, the recording and output of a magnetic field measurement value of the integrated circuit 2. To this end, the integrated circuit 2 can be placed in a mode in which the impedance measuring device is connected to the at least one current path to be tested by means of the switch 16. If necessary, this procedure can also be carried out sequentially for multiple current paths to be tested, which are arranged between the various conductors 7A, 7B, 70, 7D.

The impedance measuring device 14 can be switched off for the time periods during which the integrated circuit 2 is in normal measuring mode (measuring the magnetic field). In such a case the switch 16 is moved to the switch position shown in FIG. 4, in which the measuring connector 15 is not connected to any of the conductors 7A, 7B, 7C, 7D.

It should be mentioned that alternatively to switching off the impedance measuring device 14, components of the integrated circuit 2 intended for normal measuring operation of the integrated circuit 2, such as, for example, available analog-digital converters (ADCs) or configurable digital signal processors (DSPs), even, if present, integrated microprocessors or microcontrollers, can also be used for the impedance measurement mode in a corresponding configuration. For the period of the impedance measurement, these parts are then part of the impedance measuring device 14. This type of architecture significantly reduces the circuit complexity required.

The component 1 has a closed plastic housing 28 that encloses the integrated circuit 2 and the capacitors 3, 4, 5, 6. Every conductor 7A, 7B, 7C, 7D each has a first section enclosed by the plastic housing 28 and at least a second section exposed on the outside of the plastic housing 28 and/or projecting out from it.

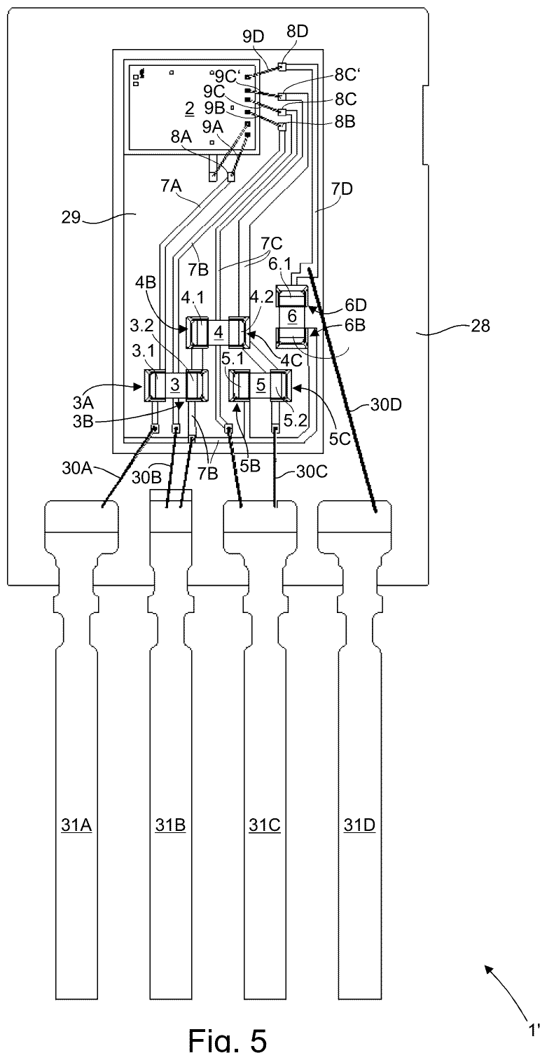

A further exemplary embodiment of the component, identified as 1′ in FIG. 5, also has a semiconductor chip with an integrated circuit 2, several hybrid capacitors 3, 4, 5, 6 integrated in the component 1′, and several electric conductors 7A, 7B, 7C, 7D. Conductor 7A and 7D are designed as conductor paths and conductor 7B and 7C have conductor paths and bonding wires that connect the conductor paths to one another. The conductor paths run on and/or in a printed circuit board 29. The integrated circuit 2 is also arranged on the printed circuit board 29.

Every conductor 7A, 7B, 7C, 7D each has a first contact point 8A, 8B, 8C, 8C′, 8D, which is connected to a contact element, structured as a bond pad, of the integrated circuit 2 that is assigned to the applicable conductor 7A, 7B, 7C, 7D, by means of at least one bonding wire 9A, 9B, 9C, 9C′, 9D.

In addition, every conductor 7A, 7B, 7C, 7D each has at least a second contact point 3A, 3B, 4B, 4C, 5B, 50, 6B, 6D that is connected, by way of a current path, in each instance, to a second contact point 6D, 6B, 5C, 5B, 4C, 4B, 3B, 3A of a further conductor 7D, 7C, 7B, 7A. A capacitor 3, 4, 5, 6 and two electrically conductive layers are arranged in every current path, in each instance, by way of which the connectors 3.1, 3.2, 4.1, 4.2, 5.1, 5.2, 6.1, 6.2 of the applicable capacitor 3, 4, 5, 6 are connected to the second contact points 3A, 3B, 4B, 4C, 5B, 5C, 6B, 6D assigned to them. The capacitors 3, 4, 5, 6 serve to suppress EMC interference and electrostatic discharge voltages that are present at the conductors 7A, 7B, 7C, 7D.

The conductor paths of conductors 7A, 7B, 7C, 7D are connected to lead frame contacts 31A, 31B, 31C, 31D by way of bonding wires 30A, 30B, 30C, 30D arranged in the plastic housing 28, each of which contacts has a first section arranged in the plastic housing 28 and a second section formed in one piece and connected with it, arranged outside the plastic housing 28.

For the remainder, the exemplary embodiment shown in FIG. 5 essentially corresponds to the first exemplary embodiment shown in FIGS. 1 through 4, so that the description of the first exemplary embodiment applies accordingly to the second exemplary embodiment.

1. An electronic component that has at least one integrated circuit, at least one capacitor, and several electrical conductors, each of which has at least a first contact point that is connected, by means of a bonding wire or similar connecting element, to a contact element assigned to the applicable conductor of the integrated circuit, whereby at least two conductors in addition to the first contact point each have at least a second contact point, and whereby the second contact points of these conductors are connected to one another by means of at least one current path, in which the capacitor, has a first electrically conductive layer connecting a first connector of the capacitor to the second contact point of a first conductor, and a second electrically conductive layer connecting a second connector of the capacitor to the second contact point of a second conductor, wherein the integrated circuit has an impedance measuring device to measure the impedance between the first contact points of the conductors that are connected to one another by way of the at least one current path, that at least one measurement signal connector of the impedance measuring device can be connected, by means of the at least one switch, to at least one of these first contact points, and that the impedance measuring device is developed for determining the equivalent ohmic series resistance between the first contact points that are connected to one another by the at least one current path.

2. The electronic component according to claim 1, wherein the impedance measuring device has a test signal generator to supply the at least one capacitor with a test signal.

3. The electronic component according to claim 2, wherein the test signal generator is designed to generate a sign-wave shaped test signal.

4. The electronic component according to claim 2, wherein the impedance measuring device
has a current measuring device to record a current flowing between the test signal generator and the conductor supplied with the test signal,
has a voltage measuring device to record the voltage on the conductor supplied with the test signal,
has a phase differential measuring device to measure the phase difference between this current and this voltage.

5. The electronic component according to claim 4, wherein the integrated circuit has a signal processing device that is connected to the current measuring device, the voltage measuring device, and the phase differential measuring device, and is designed to determine the equivalent ohmic series resistance of the electric connection between the second contact points of the conductors connected to one another by way of the at least one capacitor for this purpose, from the recorded phase difference, the measured current, and the measured voltage.

6. The electronic component according to claim 1, wherein the impedance measuring device has an output to output a measurement signal for the equivalent ohmic series resistance, that the integrated circuit has a comparator that, in order to compare the equivalent ohmic series resistance with at least one predefined threshold value, has a first comparison signal input connected to the output to output the measurement signal for the equivalent ohmic series resistance, and a second comparison signal input connected to a reference encoder.

7. The electronic component according to claim 6, wherein the integrated circuit has a means to output an error signal as a function of the comparison results.

8. The electronic component according to claim 1, wherein the integrated circuit has at least one magnetic field sensor.

9. The electronic component according to claim 1, wherein the component has a closed plastic housing that encloses the integrated circuit and the at least one capacitor.

10. The electronic component according to claim 1, wherein the conductors are designed as lead frame contacts.

11. The electronic component according to claim 9, wherein the conductors are designed as conductor paths arranged on and/or in a printed circuit board, or have such conductor paths, and that the conductor paths are arranged on a printed circuit board enclosed in a plastic housing.

12. The electronic component according to claim 11, wherein at least one of the conductors comprises at least two conductor paths that are connected to one another by at least one bonding wire arranged in the housing.

13. The electronic component according to claim 11, wherein the conductor paths of at least two conductors are connected to lead frame contacts by way of bonding wires arranged in the plastic housing, and that these lead frame contacts preferably each have at least one exposed contact surface on the outside of the housing.

14. A method for operating an electronic component, which has at least one integrated circuit, at least one capacitor, and several electrical conductors, each of which has at least a first contact point that is connected, by way of a bonding wire or similar connecting element, to a contact element assigned to the applicable conductor of the integrated circuit, whereby at least two conductors in addition to the first contact point each have at least a second contact point, whereby the second contact points of these conductors are connected to one another by way of at least one current path, in which the capacitor, has a first electrically conductive layer connecting a first connector of the capacitor to the second contact point of a first conductor, and a second electrically conductive layer connecting a second connector of the capacitor to the second contact point of a second conductor, wherein the integrated circuit is placed in a test mode, in which an impedance device for acquiring an impedance measurement signal present on the integrated circuit is connected between the conductors that are connected to one another by way of the current path, and that the equivalent ohmic series resistance between the conductors connected to one another by means of the current path is determined using the impedance measurement signal.

15. The method according to claim 14, wherein the current path is supplied with a test signal in test mode.

16. The method according to claim 15, wherein the test signal is designed as a sine wave and the equivalent ohmic series resistance is determined by measuring and evaluating the current flow and/or voltage flow and the phase differential between the current flow and voltage flow of the test signal.

17. The method according to claim 15, wherein the test signal is a step function, and the equivalent ohmic series resistance can take place through evaluation of the charging curve of the transient charging current of the capacitor.

18. The method according to claim 14, wherein the equivalent ohmic series resistance determined is compared with a predefined threshold value that and exceeding or falling below this threshold is detected.

19. The method according to claim 18, wherein depending on the result of the threshold value comparison, a result signal, in particular an error signal, is generated and output from the electronic component and/or stored in the data memory of the integrated circuit and/or that the equivalent ohmic series resistance determined is stored in the data memory.

20. The method according to claim 19, wherein at various times the equivalent ohmic series resistance is stored in the data memory, that these ohmic series resistance values can be read from the data memory and subjected to trend recognition, and upon determining a trend pointing toward an increase in the equivalent ohmic series resistance, impending exceeding of the threshold value is displayed.
